(19) United States
(12) Patent Application Publication
(10) Pub. No.: US 2001/0033621 A1
(43) Pub. Date: Oct. 25, 2001

(54) Method of differential coding and modulation

(76) Inventor: Ali S. Khayrallah, Apex, NC (US)

Correspondence Address: COATS & BENNETT, PLLC, P O BOX 5, RALEIGH, NC, 27602, US

(21) Appl. No.: 09/778,589

(22) Filed: Feb. 7, 2001

Related U.S. Application Data
(60) Provisional application No. 60/180,757, filed on Feb. 7, 2000.

(51) Int. Cl. H03M 3/00; H04B 14/06; H03D 3/22; H04L 27/22

(52) U.S. Cl. 375/244; 375/330; 341/143

(57) ABSTRACT

A method of coding information for transmission over a communication channel involves differentially coding selected bits of an input sequence with respect to bits of a previous input symbol to generate a transmit sequence comprising a plurality of transmit symbols. The differential coding method can be used in combination with unequal error protection and interleaving to protect bits during transmission.

### BACKGROUND OF THE INVENTION

This application claims the benefit of U.S. Provisional Application No. 60/180,757, filed Feb. 7, 2000.

The present invention relates generally to wireless communication systems and, more particularly, to a wireless communication system that uses differential coding in combination with a multi-pass demodulation receiver.

The purpose of any communication system is to reliably transmit information from a source to a destination over a communication channel. In a typical communication system, an information signal is error coded to protect the information signal from errors that may occur during transmission. The coded information signal is then modulated onto a carrier for transmission from the source to the destination. The transmitted signal may be corrupted by adverse effects of the communication channel, such as dispersion, interference, fading, and noise. At the destination, the original information signal must be recovered from the received signal. The received signal is demodulated to produce an estimate of the transmitted signal, which estimate is then decoded to produce an estimate of the original information signal. Ideally, the estimate of the information signal will be an exact replica of the original information signal.

In conventional communication systems, coding is performed separately from modulation in the transmitter. Likewise, demodulation and decoding are performed separately in the receiver. This separation allows reasonable complexity in the receiver, particularly when interleaving is used in the system. When interleaving is used, the output of the demodulator is first de-interleaved and then fed to the decoder. In most systems, the demodulator produces some form of bit reliability information which may be exploited by the decoder to improve performance.

It is known from information theory that the optimal receiver performs demodulation and decoding jointly. In general, joint demodulation and decoding greatly increases the complexity of the receiver, especially when interleaving is used. As an alternative to joint demodulation and decoding, it is known to use feedback from the decoder to the demodulator to improve performance of the receiver with reasonable receiver complexity. This is the idea behind multi-pass demodulation.

### BRIEF SUMMARY OF THE INVENTION

The present invention relates to a method and apparatus for coding and modulating information at a transmitter and a corresponding method and apparatus for decoding and demodulating a received signal at a receiver. According to the present invention, an input sequence comprising a plurality of input symbols is differentially coded to generate a transmit sequence comprising a plurality of transmit symbols. Differential coding is carried out by differentially coding selected bits of an input symbol with respect to one or more bits of a previous symbol to generate a transmit symbol with differentially coded bits. Some transmit symbols may contain a mixture of differentially coded bits and non-differentially coded bits. Some transmit symbols may contain exclusively differentially coded bits. Other transmit symbols may contain exclusively non-differentially coded bits. Following differential coding, the transmit symbols are input to a modulator which modulates a carrier with the transmit sequence.

At the receiver, the received signal is demodulated to produce a received sequence comprising a plurality of received symbols. Certain ones of the received symbols may include differentially coded bits, which are differentially decoded to produce an estimate of the original input sequence. If channel coding is used, the estimate of the input sequence is passed to a channel decoder, which produces an estimate of the originally-transmitted information sequence. The demodulator may be a multi-pass demodulator which uses re-encoded bits fed back from the decoder as pilot bits in second pass demodulation.

### BRIEF DESCRIPTION OF THE DRAWINGS

FIG. 1 is a functional block diagram of a communication system.

FIG. 2 is a functional block diagram of a multi-pass demodulator.

FIG. 3 is a functional block diagram of a transmitter according to the present invention.

FIG. 4 is a functional block diagram of a receiver according to the present invention.

FIG. 5 is a diagram of an eight-state equalizer trellis used in one embodiment of the present invention.

FIG. 6 is a diagram of a two-state equalizer trellis used in one embodiment of the present invention.

### DETAILED DESCRIPTION OF THE INVENTION

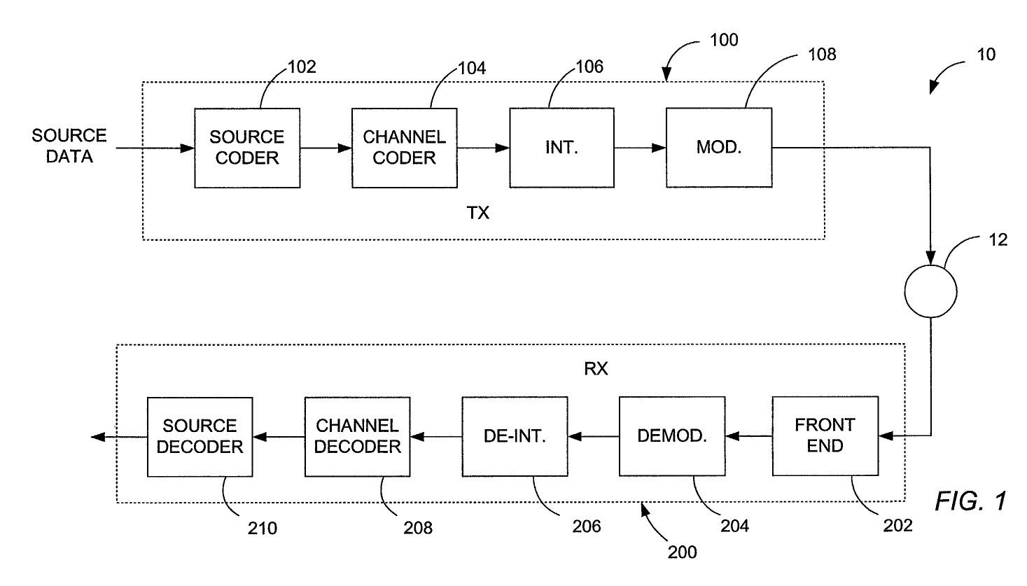

FIG. 1 illustrates a digital communication system, generally indicated by the numeral 10. The digital communication system 10 comprises a transmitter 100 and a receiver 200 which are coupled by a communications channel 12. The basic function of the communication system 10 is to transmit and information sequence from the transmitter 100 to the receiver 200 with as few errors as possible.

The transmitter 100 includes a source coder 102, a channel coder 104, optional interleaver 106, and a modulator 108. An information source provides a source data stream that is to be ultimately conveyed to the receiver 200. The source data stream is assumed to be in a digitized format and is passed directly to the source coder 102. The source coder 102 removes redundancy or randomizes the source data stream, producing an information sequence which has been optimized for maximum information content. The information sequence from the source coder 102 is passed to the channel coder 104.

Channel coder 104 is designed to introduce an element of redundancy into the information sequence output by the source coder 102, to generate a coded sequence. While initially appearing at odds with the function of the source coder 102, in reality, the redundancy added by the channel coder 104 serves to enhance the error correction capability of the communication system 10. By introducing redundant information into the information sequence in a controlled manner, a receiver 200 can detect and correct bit errors that may occur during transmission by making use of the redundant information and it's a priori knowledge of the codes used at the transmitter 100. Channel coder 104 may apply error coding to selected bits, referred to herein as protected bits. Bits not protected by error coding are referred to herein as unprotected bits. Further, protected bits may fall into two or more classes, with certain classes of bits receiving greater error protection than other classes.

Interleaver 106 permutes the ordering of the coded bits output from the channel coder 104 in a deterministic manner. It takes coded bits at an input and produces a sequence of identical bits at an output, but in a different order. Thus, the interleaver spreads bits in time. In many communication systems, some source bits are more important than other source bits. For example, a speech coder typically outputs several important bits, referred to as Class I bits, in succession. It is the function of the interleaver 106 to spread the important bits in time to protect against a deep fade, where an entire block of bits may be lost or corrupted. Interleaving effectively spreads the important bits in time so that even in a deep fade, a sufficient number of the important bits will be successfully transmitted to the receiver 200 to maintain a desired signal quality standard.

Modulator 108 receives the interleaved output from the interleaver 106 and generates waveforms that both suit the physical nature of the channel 12 and can be efficiently transmitted over the channel 12. The set of possible signal waveforms output from the modulator 108 is referred to as the signal constellation. The bits output from interleaver 106 are grouped to form symbols, which are then mapped to points on the signal constellation. For example, the input bits to the demodulator 106 may be grouped into a sequence of symbols comprising three bits each, with each bit having two possible values. In this example, the signal constellation would have eight points corresponding to the eight possible combinations of three bits. The signal constellation or modulation scheme is typically selected with regard to either simplification of the communication system, optimal detection performance, power requirements, or bandwidth availability. Typical signal constellations used in digital communication systems include 16-QAM, 8-PSK, 4-PSK, and GMSK. The output of modulator 108 is a transmit signal that is amplified and transmitted over the communication channel 12 to the receiver 200.

The basic function of the receiver 200 is to reconstruct the information sequence transmitted from the transmitter 100 from a received signal, which may have been corrupted by the communication channel 12. Receiver 200 comprises a front end circuit 202, demodulator 204, de-interleaver 206, channel decoder 208, and source decoder 210.

Front end circuit 202 is coupled to a receive antenna. Front end circuit 202 converts the received signal to the baseband frequency to generate a baseband signal, which is then sampled and digitized. The sampled and digitized baseband signal is passed to the demodulator 204. The function of the demodulator 204 is to process the received signal to determine which of the possible symbols in the signal constellation were transmitted by the transmitter 100. For example, when binary modulation is used, the demodulator 204 processes the received signal and decides at each symbol interval whether a transmitted symbol is a “0” or a “1”. The output of demodulator 204 is referred to herein as the received sequence, which is essentially an estimate of the transmit sequence. The received sequence will typically contain some bit errors.

De-interleaver 206 reorders the bits of the received sequence to undo the effects of interleaver 106, which are then input to the channel decoder 208. Channel decoder 208 attempts to detect and correct bit errors that may have occurred during transmission from the received sequence and it's a priori knowledge of the code used by the channel coder 104. A measure of how well the demodulator 204 and channel decoder 208 perform is the frequency with which bit errors occur in the decoded sequence.

As a final step, a source decoder 210 accepts the decoded output from the channel decoder 208 and, from knowledge of the source encoding method, attempts to reconstruct the original source data stream. The difference between the reconstructed source data stream and the original source data stream is a measure of the distortion introduced by the digital communication system 10.

In conventional digital communication systems 10, coding and modulation are performed separately at the transmitter 100. Likewise, demodulation and decoding are performed in separate operations at the receiver 200. The demodulator 204 decides what symbols were transmitted based on the received signal. The decisions by the demodulator 204 may be hard decisions or soft decisions that include reliability information. The channel decoder 208 then processes the decisions by the demodulator 204 using bit reliability information when available to detect and correct errors that may have occurred during transmission.

One commonly used modulation scheme is coherent phase shift keying (PSK). In coherent 8-PSK, each transmitted symbol Y(i) comprises three bits, denoted y₁(i), y₂(i), and y₃(i). Each transmit symbol Y(i) maps to one point on the signal constellation. For example, each transmit symbol Y(i) may be mapped to the signal constellation using Gray coding, which means that all adjacent points on the signal constellation vary at only a single bit position. Coherent 8-PSK provides good performance in flat-fading channels with an adequate signal-to-noise ratio. However, receiver performance can suffer at low signal-to-noise ratios. This circumstance arises in time-varying channels where the phase of the signal is corrupted by, for example, Doppler effects and multipath propagation. In such cases, it may be desirable to employ a technique known as differential modulation.

Differential PSK (DPSK) is a non-coherent form of phase shift keying which avoids the need for a coherent reference signal at the receiver 200. Non-coherent receivers are relatively easy and inexpensive to build and, hence, are widely used in wireless communications. In DPSK systems, each symbol (grouping of bits) maps to a differential phase ΔΦ. The differential phase ΔΦ is then used to determine the phase of the transmitted signal at symbol interval i according to the relation Φᵢ=Φᵢ₋₁+ΔΦᵢ. Thus, in DPSK, the phase of each transmitted symbol y₁(i) is determined by the phase of the previously-transmitted symbol Y(i−1) and the differential phase ΔΦ. Thus, the received signal can be demodulated by comparing symbols only one symbol period apart, a sufficiently short time span so that channel phase changes insignificantly over that time period. Unfortunately, changing from coherent to differential modulation increases the number of certain error events and results in a loss of about 3 dB for all three bits.

One way to improve receiver performance is to combine demodulation and channel decoding using feedback from the channel decoder to the demodulator. This technique is referred to as multi-pass demodulation. In a multi-pass demodulation receiver, the received signal is initially demodulated and decoded in conventional fashion. The decoded bits are then re-encoded and selected ones of the re-encoded bits are fed back to the demodulator. The received signal is demodulated a second time. During the second pass through the demodulator, the re-encoded bits are treated as known bits or pilot bits by the demodulator. This process can be repeated multiple times, at the cost of increased complexity. Typically, the largest benefit occurs with the first few passes.

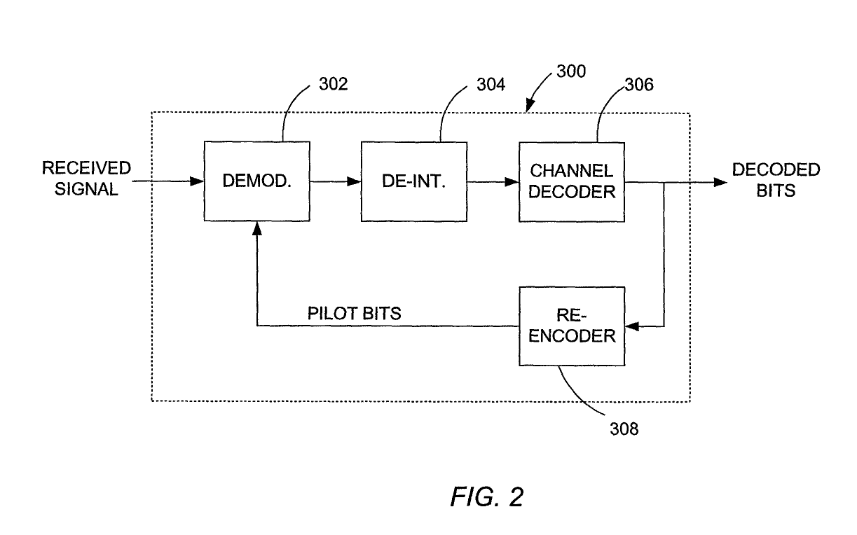

FIG. 2 is a block diagram of a multi-pass demodulation receiver 300. Multi-pass demodulation receiver 300 comprises a demodulator 302, de-interleaver 304, channel decoder 306, and re-encoder 308. The received signal is converted to the baseband frequency and input to demodulator 203. During the first pass through the demodulator 302, the received signal is demodulated in a conventional fashion. The received sequence output from demodulator 302 is fed to de-interleaver 304, which reorders the bits of the received sequence. The output from de-interleaver 304 is fed to channel decoder 306, which detects and corrects errors that may have occurred during transmission. The output from channel decoder 306 is an estimate of the original information sequence transmitted from the transmitter 100. The output from channel decoder 306 is then re-encoded in re-encoder 308 and selected ones of the re-encoded bits are fed back to the demodulator 302 to use as pilot bits in second pass demodulation. During second pass demodulation, the re-encoded bits fed back from channel decoder 306 are treated as known bits by the demodulator 302. Thus, during second pass demodulation, the demodulator 302 is constrained to output symbols that meet the known bit pattern. The re-encoded bits output by channel decoder 306 may be “hard bits” or may be “soft bits” reflecting the level of confidence in the decision. In either case, well-known methods exist for exploiting the decisions in the demodulator 302.

Multi-pass demodulation may be particularly useful where the bits of a transmitted symbol have unequal error protection. The bits with the greatest error protection are decoded after the first pass through the demodulator 302 with a relatively high degree of certainty. The strongly coded bits may be treated as known bits in a second pass through the demodulator 302 to assist the demodulation of more weakly coded bits or unencoded bits. Demodulation in a multi-pass demodulation receiver 300 may involve two or more passes through the demodulator 302 with more bits treated as known bits after each pass through the demodulator 302. An example of a multi-pass receiver 300 is described in U.S. Pat. No. 5,673,291 to Dent, which is incorporated herein by reference.

The present invention employs a technique referred to as differential coding in combination with higher order modulation to improve receiver performance. Error coding and interleaving may also be used. According to the present invention, a differential relation is established at the bit level between successive transmit symbols. The present invention is particularly suited to communication systems 10 with unequal error protection and diagonal interleaving, which are typically used for protecting speech. The invention is applicable to a wide range of communication protocols and technologies, including standards published by the Telecommunication Industry Association (TIA) and Electronics Industry Association (EIA) known as TIA/EIA-136, and the Bluetooth standard. Numerous variations of the differential coding scheme are possible, a few of which are described below to illustrate the flexibility afforded by differential coding.

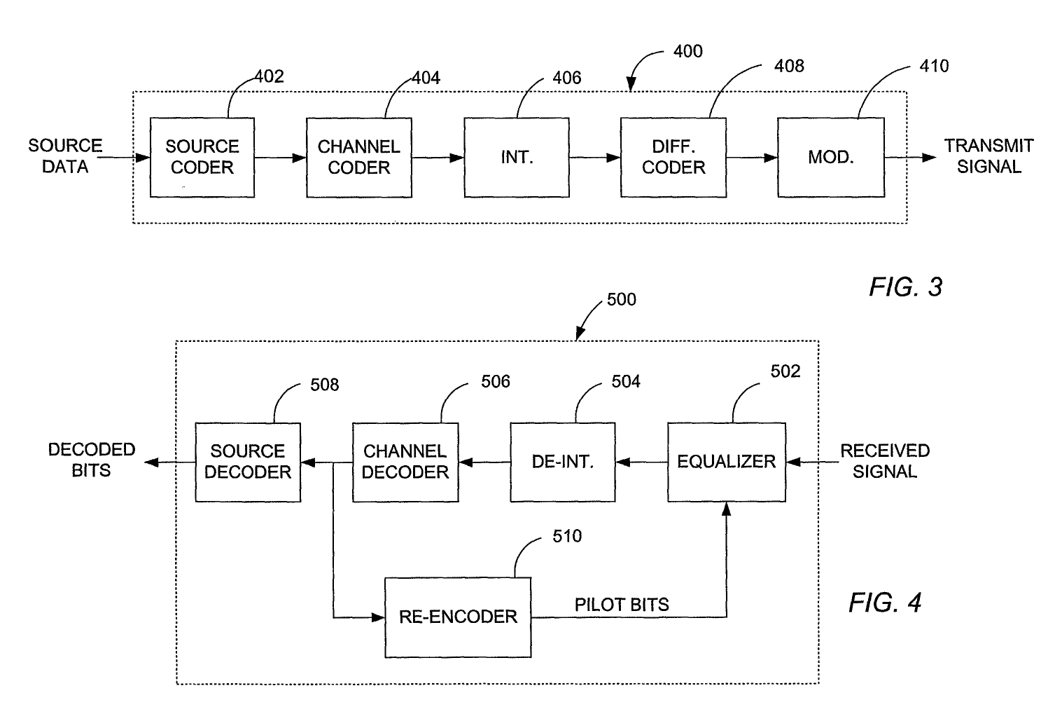

FIG. 3 is a functional block diagram of a transmitter 400 according to the present invention that employs differential coding. The transmitter 400 is similar to a conventional transmitter 100 but includes a differential coder 408 to establish a differential relation between transmit symbols spaced in time. The transmitter 400 of the present invention comprises a source coder 402, channel coder 404, interleaver 406, differential coder 408, and modulator 410. Source coder 402, channel coder 404, and interleaver 406 perform the same functions as their counterparts in the conventional transmitter 100. It is to be noted that source coder 402, channel coder 404, and interleaver 406 are not essential elements of the inventive receiver 400 but one or more of these elements will typically be present.

In the illustrated embodiment of the invention, differential coder 408 receives the output from interleaver 406. Differential coder 408 could also receive output directly from channel coder 404 or source coder 402. In any case, differential coder 408 receives a bit sequence at its input, referred to herein as the input sequence, which is divided into successive symbols, referred to herein as input symbols. The function of the differential coder 408 is to produce a transmit sequence comprising a plurality of transmit symbols based on the input sequence by differentially coding selected bits of the input sequence. Differential coding may be performed, for example, by coding a selected bit of each input symbol with respect to one or more bits from one or more previous input symbols. In this example, the transmit sequence will comprise some bits which are differentially coded and others which are not differentially coded. It is not necessary that every transmit symbol include differentially coded bits. Some transmit symbols may be comprised entirely of differentially coded bits, while others contain no differentially encoded bits. Furthermore, some transmit symbols may comprise a mixture of differentially coded bits and non-differentially coded bits.

Modulator 410 receives the transmit sequence from differential coder 408 and modulates the transmit sequence onto a carrier. Modulator 410 may, for example, comprise a coherent 8-PSK modulator or a coherent 16-QAM modulator. However, those skilled in the art will recognize that the differential coding scheme may also be used with other higher order modulation schemes.

Referring now to FIG. 4, a receiver 500, according to the present invention, is shown. Receiver 500 comprises an equalizer 502, de-interleaver 504, channel decoder 506, source decoder 508, and re-encoder 510. The de-interleaver 504, channel decoder 506, and source decoder 508 perform the same functions as their counterparts in receivers 200 and 300. These elements are not essential parts of the inventive receiver 500; however, one or more of these elements will typically be present. Similarly, re-encoder 510 performs the same function as its counterpart in receiver 300. Re-encoder 510 may advantageously be present when multi-pass demodulation is used, but it is not an essential element of the invention.

The function of equalizer 502 is to demodulate and differentially decode a received signal. In the illustrated embodiment, demodulation and differential decoding are performed jointly by equalizer 502. However, those skilled in the art will recognize that demodulation and decoding could be performed separately. That is, equalizer 502 could be replaced by a separate demodulator and differential decoder. In that case, the demodulator would output a received sequence comprising a plurality of received symbols which would then be fed to a differential decoder. The received sequence is, in essence, an estimate of the transmit sequence input to the modulator 410 at the transmitter 400. The differential decoder would, in that case, differentially decode the received sequence and generate an output sequence, which is essentially an estimate of the original input sequence to the differential coder 408 at the transmitter 400. However, an equalizer 502 can perform both operations, processing the received signal to generate the output sequence, without the intermediate step of generating a received sequence. Instead, differential decoding of the received sequence is performed by equalizer 502 jointly with demodulation.

Several examples of the differentially coding method of the present invention are given below. These examples assume that the same coding scheme is applied to each input symbol so that each transmit symbol in the transmit sequence comprises at least one differentially coded bit.

In the illustrations below, the modulation scheme employed is coherent 8-PSK. The transmit symbol, generally noted Y(i), maps directly to a point on the 8-PSK signal constellation. The transmit symbol Y(i) comprises three bits y₁(i), y₂(i), and y₃(i). The transmit symbol Y(i) is derived from the input symbol, generally denoted X(i). As will be explained below, the bits of the transmit symbol Y(i) are differentially encoded.

### EXAMPLE 1

In a first example, the transmit symbol Y(i) is derived from the input symbol X(i) as follows:

y₁(i)=x₁(i)

y₂(i)=x₂(i)+y₃(i−1)

y₃(i)=x₃(i) Eq. 1

As shown in Equation 1, the bits y₁ and y₃ of the transmit symbol Y(i) are the same as the bits x₁ and x₃, respecffully, of the input symbol X(i), while bit y₂ is a differentially coded bit. That is, bit y₂ in the transmit symbol Y(i) is differentially coded with respect to bit y₃ from the previous transmit symbol, denoted as y₃(i−1). Bit x₂(i) of the transmit symbol may be a protected bit, or may be an unprotected bit. Similarly, bit x₃ of the previous input symbol X(i−1), which is used in the differential relation, may be a protected bit or an unprotected bit.

In a computer simulation performed by the inventor, the differential coding and modulation scheme of the present invention was compared to conventional coherent 8-PSK modulation. In particular, the simulation compared the Bit Error Rate (BER) vs. C/N performance of the inventive receiver 500 to a conventional receiver 200 employing coherent 8-PSK modulation. As expected, the bit error rate for bits x₁ and x₃ of the input symbol X(i) are the same as the corresponding bits in coherent 8-PSK modulation. The bit error rate for bit x₂ of the input symbol X(i) is more than double its counterpart in coherent 8-PSK. This increased bit error rate is due to the differential relation of bit y₂ of the transmit symbol Y(i) with respect to bit y₃ of the previous transmit symbol Y(I−1).

Multi-pass demodulation may be used to improve bit error performance at the cost of slightly greater receiver complexity. Assume that bits x₁ and x₂ are coded bits, and that bit x₃ is an uncoded bit. Further assume that bits x₁ and x₂ are fed back to the demodulator which produces a new estimate for x₃. Knowledge of x₂ improves the bit error rate of x₃. In the simulation, it was found that the bit error rate of x₃ following a second pass through the demodulator results in a 2 dB improvement in the bit error performance as compared to coherent 8-PSK modulation.

### EXAMPLE 2

In this example, the transmit symbol Y(i) is related to the input symbol X(i) as follows:

y₁(i)=x₁(i)

y₂(i)=x₂(i)+y₁(i−1) y₃(i)=x₃(i) Eq. 2

As shown in Equation 2, y₁ and y₃ of transmit symbol Y(i) are the same as bits x₁ and x₃, respectively, of input symbols X(i). However, bit y₂ of transmit symbol Y(i) is differentially coded with respect to bit y₁(i−1) of the previous transmit symbol Y(i−1). In general, the bit error rate for bit y₁ in 8-PSK modulation is less than the bit error rate for bit y₃. Consequently, the bit error rate for input bit x₂ is slightly improved as compared to the previous example, but still lower than conventional coherent 8-PSK modulation. The reduced performance is due to the differential relation. Again, multi-pass demodulation can be used to further improve performance. In second pass demodulation, input bits x₂ and x₃ are fed back and used as pilot bits to improve the bit error rate of input bit x₁ during second pass demodulation. The result is an improvement in the bit error rate for input bit x₁. The gain for input bit x₁ as compared to conventional coherent 8-PSK is about 4 dB. Additionally, it is noted that the bit error performance for input bits x₂ and x₃ are the same. This is beneficial since both of these bits are fed back to the decoder 506 and standard decoders expect bits of the same reliability.

### EXAMPLE 3

In this example, the transmit symbol Y(i) is related to the input symbol X(i) as follows:

y₁(i)=x₁(i)

y₂(i)=x₂(i)

y₃(i)=x₃(i)+y₂(i−1)+y₁(i−1) Eq. 3

Bits y₁ and y₂ of the transmit symbol Y(i) are the same as bits x₁ and x₂ of the input symbol X(i). Bit y₃ of the transmit symbol is differential with respect to bits y₂ and y₁ from the previous transmit symbol Y(i−1). In the absence of multi-pass demodulation, the bit error performance for bits x₁ and x₂ following demodulation are the same as in coherent 8-PSK, while the bit error performance for bit x₃ is worse. Improved performance can be obtained using multi-pass demodulation. More particularly, bit x₃ may be fed back from decoder 506 to assist demodulation of bits x₁ and x₂ during second pass demodulation. In simulations performed by the inventor, an improvement of about 2 dB was realized in both bits x₁ and x₂ following second pass demodulation. The differential coding and modulation scheme illustrated by this example may be useful in situations where bit x₃ of input symbol X(i) is a protected bit, while bits x₁ and x₂ are either uncoded or have less error protection than bit x₃.

### EXAMPLE 4

In this example, the transmitted symbol Y(i) is related to the input symbol X(i) as follows:

y₁(i)=x₁(i)+y₂(i−1)

y₂(i)=x₂(i)+y₃(i−1)

y₃(i)=x₃(i) Eq. 4

Bit y₃ of the transmit symbol Y(i) is identical to bit x₃ of the input symbol X(i). Bit y₁ of the transmit symbol Y(i) is differential with respect to bit y₂ from the previous transmit symbol Y(i−1) while bit y₂ is differential with respect to bit y₃ of the previous transmit symbol Y(i−1). After single pass demodulation, the bit error performance for bit x₃ is the same as conventional coherent 8-PSK. The bit error performance for bit x₁ is lower than coherent 8-PSK and is the same as the bit error performance of bit x₂ in Example 2. The bit error performance for bit x₂ is substantially below the bit error performance of the same bit using coherent 8-PSK without differential coding. Improved bit error performance can be obtained using multi-pass demodulation. More particularly, bit x₁ of transmit symbol X(i) may be fed back from decoder 506 to improve demodulation of bit x₂ during second pass demodulation. Alternatively, bit x₁ and bit x₃ of transmit symbol X(i) may both be fed back to improve the bit error performance of bit x₂ during second pass demodulation. In the first case, the improvement is small because bit x₁ is the “coherent” part of the differential relation as seen in Equation 4. In the second case, significant improvement in bit error performance for bit x₂ may be realized. The gain as compared to coherent 8-PSK is about 4.5 dB. As in the second example, bits x₁ and x₃ have the same reliability (i.e., bit error performance), which benefits decoding.

### EXAMPLE 5

In this example, the transmit symbol Y(i) is related to the input symbol X(i) as follows:

y₁(i)+x₁(i)

y₂(i)=x₂(i)+y₁(i−1)

y₃(i)=x₃(i)+y₁(i−1) Eq. 5

Bit y₁ of the transmit symbol is identical to bit x₁ of the input symbol. Bits y₂ and y₃ of the transmit symbol are both differential with respect to bit y₁ of the previous transmit symbol Y(i−1). Following single path demodulation, the bit error performance for bit x₁ is the same as in coherent 8-PSK, while the bit error performance for bits x₂ and x₃ is lower due to the differential relation. The bit error performance for bit x₂ is the same as for bit x₂ in Example 2. The bit error performance for bit x₃ is slightly better than bit x₃ in Example 3, which is differential with respect to two bits instead of one in the present example. Again, improvements in bit error performance can be obtained by multi-pass demodulation. Using multi-pass demodulation, bit x₂ may be fed back to improve the bit error performance of bits x₁ and x₃. Alternately, bits x₂ and x₃ may be fed back to improve the bit error performance of bit x₁. In the first case, the improvement in bit error performance of bit x₃ is small since bit x₃ is only indirectly related to bit x₂. In the second case, there is an improvement in the bit error performance of bit x₁. The gain over coherent 8-PSK is about 5 dB.

In all of the above examples, equalizer 502 can be implemented as an eight state equalizer. It is assumed that coherent demodulation is used, where the channel is estimated and used in the demodulation process. Channel estimation is well known to those skilled in the art and is not addressed further in the present application.

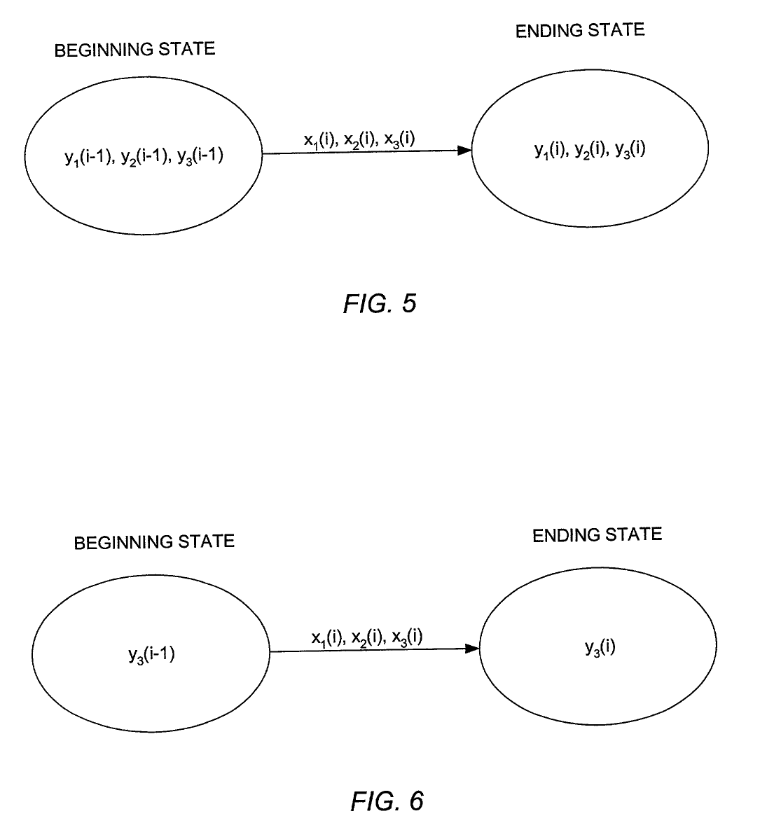

FIG. 5 is a diagram of an eight-state equalizer trellis that may be used by equalizer 502. The states represent possible values for the transmit symbol Y(n). The transitions are associated with an input symbol X(n) that causes the transition from one state to the next state. The values of the input symbol X(n) that cause the transition are determined by the differential relation. For example, in an equalizer 502 that implements Example 1, the value of the transitions is determined by the following relation which is derived from Equation 1:

x₁(i)=y₁(i)

x₂(i)=y₂(i)+y₃(i−1) x₃(i)=y₃(i) Eq. 6

Examples 1-6 can all be handled by the same eight-state equalizer 502 with Equation 6 above replaced by the appropriate relation for Examples 2-5. In all cases, there is a transition from each of the eight possible beginning states Y₁(i−1) to each of the eight possible ending states Y₁(i). Given this trellis, demodulation and decoding can be carried out using the Viterbi algorithm or MAP algorithm, both of which are well known in the art.

In the case of coherent 8-PSK, the demodulator does not need a state for each possible value of the transmit symbol X(i) since modulation is memoryless in the absence of dispersion. Thus, the eight states can be collapsed into a single state. The same approach can be taken with the differential coding and modulation schemes of the present invention. For a non-dispersive channel, where knowledge of all eight states is not necessary, it is possible to reduce the number of states, provided the differential relation is taken into account. In the first example, it can be seen from Equation 1 that the equalizer 502 needs to have a state for bit y₃ only, so the eight states can be collapsed into two states representing the possible values of y₃. In the second example, Equation 2 indicates that the eight states can be collapsed into two states representing y₃. In the third example, Equation 3 shows that the eight states can be collapsed to four states representing all possible combinations of y₁ and y₂. In Example 4, Equation 4 indicates that the eight states can be collapsed into four states representing possible combinations of y₂ and y₃. Finally, in the last example, Equation 5 indicates that the eight states can be collapsed into two states representing y₁.

FIG. 6 is a diagram illustrating a two-state trellis corresponding to Example 1. There are two possible values for the beginning state y₃(i−1) and two possible values for the ending state y₃(i). There are four transitions from each of the two beginning states y₃(i−1) to each of the two ending states y₃(i). The four transitions account for the four possible combinations of y₁(i) and y₂(i). Reduced-size trellises corresponding to Examples 2-5 can be devised in similar fashion.

It is always possible to use an eight-state equalizer for demodulation and decoding, even though a lesser number of states would suffice. The redundant states do not hurt bit error performance but would require additional computations and memory without providing any advantage. It is to be noted, however, that if a receiver 500 is designed to handle a number of different differential coding schemes, it may be advantageous to always use the same eight state equalizer 502, which can be built as an efficient hardware circuit, for instance. More generally, the equalizer trellis needs to have the number of states required to fully represent the relations defined by the differential coding. Thus, if all three bits from a previous transmit symbol Y(i−1) are used in differential relations for a current transmit symbol Y(i), then the equalizer 502 needs to have eight states. Similarly, if the differential relations involve all three bits of the previous transmit symbol, as well as three bits from the transmit symbol two periods before the current symbol, then the equalizer 502 needs to have sixty-four states.

So far, it has been assumed that the communication channel is a flat, fading channel, which can be represented by a single channel tap in the equalizer 502. In the case of dispersive channels, an equalizer 502 is required to take dispersion into account. Fortunately, the same equalizer 502 that handles differential decoding is also capable of handling channel dispersion. The eight-state equalizer 502 described above can handle a two-tap symbol-spaced dispersive channel. A sixty-four-state equalizer 502 can handle a three-tap channel, and so on. It should also be noted that differential coding and channel dispersion can share states. In other words, the memory they introduce does not necessarily add. In contrast, the memory due to a partial response modulation scheme and a dispersive channel adds, so that the equalizer state space needs to grow to handle both.

The differential coding method can also be used with other higher-order modulation schemes. The following examples illustrate the use of the differential coding scheme of the present invention, in combination with 16-quadrature amplitude modulation (QAM). In standard coherent 16-QAM, the transmit symbol Y(i) comprises four bits y₁(i), y₂(i), y₃(i), y₄(i) which map directly to a point on the signal constellation. In the following discussion, it is assumed that Gray code mapping is used. When Gray code mapping is used, bits x₁(i) and x₃(i) have the same performance. Bits x₂(i) and x₄(i) exhibit worst performance by a factor slightly less than two. Bits x₁ and x₃ are referred to as the “good” bits and bits x₂ and x₄ are referred to as the “bad” bits. For each of the examples given below, the BER versus C/N performance in a flat Rayleigh-fitting channel was simulated.

### EXAMPLE 6

In this example, the transmit symbol Y(i) is derived from the input symbol X(i) as follows:

y₁ (i)=x₁(i) y₂(i)=x₂(i)+y₁(i−1)

y₃(i)=x₃(i)

y₄(i)=x₄(i)+y₃(i−1) Eq. 7

In this example, bits y₁ and y₃ of the transmit symbol Y(i) are the same as in coherent 16-QAM. Bits y₂ and y₄ of the transmit symbol Y(i) are differential with respect to the first bit and the third bit of the previous transmit symbol, denoted y₁(i−1), respectively. The bit error performance for bits x₁ and x₃ of the input symbol X(i) are the same as in coherent 16-QAM. In second pass demodulation, bits x₂ and x₄ of the input symbol X(i) are fed back to the equalizer 502 and used as pilots to assist demodulation of bits x₁ and x₃. The gain for bits x₁ and x₃ as compared to the same bits for 16-QAM is about 2 dB. Note that bits x₂ and x₄, which are fed back and used as pilot bits, have the same bit error performance. As previously described, this is beneficial for decoding since standard decoders expect bits of the same reliability.

### EXAMPLE 7

In this example, the transmit symbol Y(i) is derived from the input symbol X(i) as follows:

y₁(i)=x₁(i)

y₂(i)=x₂(i)

y₃(i)=x₃(i)+y₁(i−1)

y₄(i)=x₄(i) Eq. 8

In this example, bits y₁ and y₃ of the transmit symbol Y(i) are the same as in coherent 16-QAM. Bits y₂ and y₄ of the transmit symbol Y(i) are differential with respect to the first bit and the third bit of the previous transmit symbol, denoted y₁(i−1), respectively. The bit error performance for bits x₁, x₂, and x₄ are the same as in coherent 16-QAM after first pass demodulation. Some improvement can be obtained by multi-pass demodulation. In particular, bit x₃ may be fed back to equalizer 502 and used as a pilot bit to assist demodulation of bit x₁. In this case, the bit error performance for bit x₁ is improved over coherent 16-QAM by about 4 dB. There is no improvement in the bit error performance of bits x₂ and x₄.

### EXAMPLE 8

In this example, the transmit symbol Y(i) is derived from the input X(i) as follows:

y₁(i)=x₁(i)

y₂(i)=x₂(i)+y₁(i−1)

y₃(i)=x₃(i)+y₁(i−1)

y₄(i)=x₄(i)+y₁(i−1) Eq. 9

Bit y₁(i) of the transmit symbol Y(i) is the same as bit x₁(i) of the input symbol X(i). Bits y₂, y₃, and y₄ of the transmit symbol Y(i) are differential with respect to bit y₁ of the previous transmit symbol. Following first pass demodulation, the bit error performance for bit x₁ is the same as in coherent 16-QAM. The performance of bits x₂, x₃, and x₄ is less favorable than coherent 16-QAM. In second pass demodulation, bits x₂, x₃, and x₄ may be fed back and used as pilot bits to assist demodulation of bit x₁. In this case, the improvement in bit error performance of bit x₁ is about 5 dB as compared to coherent 16-QAM.

A number of examples of the differential coding method of the present invention have been given showing the differential coding method used in connection with 8-PSK and 16-QAM modulation. Those skilled in the art will appreciate that the differential coding method of the present invention may also be used with other higher-order modulation techniques.

The differential coding and modulation scheme presented here is particularly well suited for a communication system 10 with unequal error protection. For example, consider a system with a set of strongly-coded bits, a set of weakly-coded bits, and a set of unencoded bits. Further assume that multi-pass demodulation is used. Following first pass demodulation, the strongly-coded bits are decoded and fed back from the decoder 506 to help demodulate the weakly-coded bits in second pass demodulation. Following second pass demodulation, the weakly-coded bits are decoded and fed back, along with the strongly-coded bits, to assist demodulation of the unencoded bits. In each pass, the differential coding helps spread the effect of coding to other bits, improving bit error performance.

Another situation where differential coding and multi-pass demodulation are useful is in communication systems 10 that employ diagonal interleaving. In the simplest case of diagonal interleaving, a frame of data at the output of an encoder is split equally among two bursts transmitted over a channel. Each burst contains equal amounts of data from two consecutive frames. At the receiver 500, when one burst is demodulated, half of the demodulated output is used to complete the set of data required to decode one frame and the other half is stored, awaiting the next burst. When a frame is decoded and fed back to the equalizer 502 for second pass demodulation, the half frame which is stored is improved. Thus, differential coding and multi-pass demodulation benefit a communication system 10 with diagonal interleaving, even in the absence of unequal error protection. More general forms of diagonal interleaving exist, involving multiple frames and multiple bursts, but the same principle holds for them as well.

When designing systems using differential coding and multi-pass demodulation, placement of pilot bits and non-pilot bits within a symbol must be considered. In the above examples, the same bit or bits within each symbol serve as pilots, which are fed back to assist in second pass demodulation. It is also possible to have symbols with different pilot assignments within a single burst. One simple case is where some symbols consist exclusively of pilots, and other symbols contain a mix of pilots and non-pilot bits. This asymmetric approach may be useful, for instance, in order to accommodate encoded and unencoded bits in a burst when their numbers do not easily fit into a consistent assignment scheme. Another simple case is where some symbols consist exclusively of non-pilots because pilot bits have been exhausted. In general, it is possible to use a variable number of pilot bits per symbol, as well as a variable differential coding relation.

The present invention may, of course, be carried out in other specific ways than those herein set forth without departing from the scope and essential characteristics of the invention. The present embodiments are, therefore, to be considered in all respects as illustrative and not restrictive, and all changes coming within the meaning and equivalency range of the appended claims are intended to be embraced therein.

What is claimed is:

1. A method of coding information for transmission over a communication channel, said method comprising:
generating a transmit sequence comprising a plurality of transmit symbols based on an input sequence comprising a plurality of input symbols by differentially coding selected bits of said input sequence to produce one or more differentially coded bits in said transmit sequence.

2. The method of claim 1 wherein differentially coding selected bits of said input sequence to produce one or more differentially coded bits in said transmit sequence comprises differentially coding one or more bits of a first input symbol with respect to one or more bits from one or more previous input symbols.

3. The method of claim 2 wherein differentially coding one or more bits of said first input symbol with respect to one or more bits from one or more previous input symbols comprises differentially coding at least one protected bit of said first input symbol.

4. The method of claim 3 wherein differentially coding said at least one protected bit of said first input symbol comprises differentially coding said at least one protected bit of said first input symbol with respect to a less protected bit of a previous transmit symbol.

5. The method of claim 2 wherein differentially coding one or more bits of a first input symbol with respect to one or more bits from one or more previous transmit symbols comprises differentially coding at least one unprotected bit of said first input symbol.

6. The method of claim 5 wherein differentially coding at least one unprotected bit of said first input symbol comprises differentially coding said unprotected bit of said first input symbol with respect to a protected bit of a previous transmit symbol.

7. The method of claim 1 further comprising generating said input sequence based on an information sequence.

8. The method of claim 8 wherein generating said input sequence based on said information sequence comprises channel coding bits of said information sequence to produce a coded sequence.

9. The method of claim 8 wherein channel coding bits of said information sequence to produce said coded sequence comprises error coding said information sequence using an unequal error protection scheme.

10. The method of claim 8 wherein generating said input sequence based on said information sequence further comprises interleaving bits of said coded sequence to produce said input sequence.

11. The method of claim 10 wherein interleaving bits of said coded sequence to produce said input sequence comprises diagonally interleaving bits of said coded sequence to produce said input sequence.

12. The method of claim 1 further comprising modulating a carrier with said transmit sequence to produce a transmit signal.

13. A method of decoding a received sequence comprising:
differentially decoding a received sequence comprising a plurality of received symbols to generate an output sequence comprising a plurality of output symbols, said received sequence having one or more differentially coded bits.

14. The method of claim 13 further comprising demodulating a received signal to generate said received sequence.

15. The method of claim 14 wherein demodulating said received signal to generate said received sequence and differentially decoding said received sequence to generate said output sequence are performed jointly in an equalizer.

16. The method of claim 13 further comprising channel decoding said output sequence to generate a decoded sequence.

17. The method of claim 16 wherein demodulating a received signal to generate said received sequence comprises demodulating said received signal using re-encoded bits fed back from a channel decoder as pilot bits.

18. The method of claim 17 further comprising outputting said re-encoded bits from said channel decoder.

19. The method of claim 17 further comprising re-encoding said decoded sequence to produce said re-encoded bits.

20. The method of claim 13 wherein differentially decoding said received sequence comprising said plurality of received symbols to generate said output sequence comprising said plurality of output symbols comprises differentially decoding one or more bits of a first received symbol with respect to one or more bits from one or more previous received symbols.

21. The method of claim 20 wherein differentially decoding one or more bits of said first received symbol with respect to one or more bits from said one or more previous received symbols comprises differentially decoding at least one protected bit of said first received symbol.

22. The method of claim 21 wherein differentially decoding said at least one protected bit of said first received symbol comprises differentially decoding said at least one protected bit of said first received symbol with respect to a less protected bit of a previous received symbol.

23. The method of claim 20 wherein differentially decoding one or more bits of said first received symbol with respect to one or more bits from said one or more previous received symbols comprises differentially decoding at least one unprotected bit of said first received symbol.

24. The method of claim 23 wherein differentially decoding said at least one unprotected bit of said first received symbol comprises differentially decoding said unprotected bit of said first received symbol with respect to a protected bit of a previous received symbol.

25. An apparatus for coding an input sequence to generate a transmit sequence, said apparatus comprising:
a differential coder to generate a transmit sequence comprising a plurality of transmit symbols based on an input sequence comprising a plurality of input symbols by differentially coding selected bits of said input sequence to produce one or more differentially coded bits in said transmit sequence.

26. The apparatus of claim 25 wherein said differential coder differentially codes one or more bits of a first input symbol with respect to one or more bits from one or more previous transmit symbols.

27. The apparatus of claim 26 wherein said differentially coded bits comprise at least one protected bit.

28. The apparatus of claim 27 wherein said at least one protected bit is differentially coded with respect to a less protected bit of a previous transmit symbol.

29. The apparatus of claim 26 wherein said differentially coded bits comprises at least one unprotected bit.

30. The method of claim 29 wherein said at least one unprotected bit is differentially coded with respect to a protected bit of a previous transmit symbol.

31. The apparatus of claim 25 further including a channel coder to channel code an information sequence to generate said input sequence.

32. The apparatus of claim 31 wherein said channel coder codes said information sequence using an unequal error protection scheme.

33. The apparatus of claim 31 further comprising an interleaver to interleave coded bits output by said channel coder to generate said input sequence.

34. The apparatus of claim 33 wherein said interleaver is a diagonal interleaver.

35. The apparatus of claim 25 further comprising a modulator following said differential coder to modulate said transmit sequence onto a carrier.

36. An apparatus for decoding a received sequence comprising:
an equalizer to differentially decode a received sequence comprising a plurality of received symbols to generate an output sequence comprising a plurality of output symbols, said received sequence having one or more differentially coded bits.

37. The apparatus of claim 36 further comprising a demodulator to demodulate a received signal to generate said received sequence.

38. The apparatus of claim 37 wherein said demodulator and said differential decoder are implemented as an equalizer that performs demodulation and differential decoding jointly.

39. The apparatus of claim 38 further comprising a channel decoder to decode said output sequence output from said differential decoder to generate a decoded sequence.

40. The apparatus of claim 39 wherein said demodulator comprises a multi-pass demodulator that receives re-encoded bits fed back from said channel decoder, wherein said reencoded bits are used as pilot bits by said demodulator to demodulate said received signal.

41. The apparatus of claim 36 wherein said differential decoder differentially decodes one or more bits of a first received symbol with respect to one or more bits from previous received symbols.

42. The apparatus of claim 41 wherein at least one differentially coded bit comprises a protected bit, and wherein said protected bit is differentially decoded with respect to a less protected bit of a previous received symbol.

43. The apparatus of claim 41 wherein at least one differentially coded bit comprises an unprotected bit, and wherein said unprotected bit is differentially decoded with respect to a protected bit.
